(19) United States
(12) Patent Application Publication
(10) Pub. No.: US 2024/0315116 A1
(43) Pub. Date: Sep. 19, 2024

(54) DISPLAY DEVICE

(71) Applicant: Samsung Display Co., Ltd., Yongin-si (KR)

(72) Inventors: JEONGKI KIM, Yongin-si (KR); JONG-HOON KIM, Yongin-si (KR); JANG-IL KIM, Yongin-si (KR); SI-WAN JEON, Yongin-si (KR); SEOK-JOON HONG, Yongin-si (KR)

(73) Assignee: Samsung Display Co., Ltd., Yongin-si (KR)

(21) Appl. No.: 18/406,753

(22) Filed: Jan. 8, 2024

(30) Foreign Application Priority Data
Mar. 15, 2023 (KR) 10-2023-0033642

(51) Int. Cl. H10K 59/80; H10K 59/122

(52) U.S. Cl. CPC H10K 59/875; H10K 59/122

(57) ABSTRACT

Provided is a display device including a display panel including a light emitting element layer and a light control layer on the light emitting element layer, and a color filter panel on the display panel, the color filter panel includes a base layer, a color filter layer below the base layer, a low refractive layer below the color filter layer, and a spacer between the color filter layer and the low refractive layer, and sides of the spacer are covered by the low refractive layer.

### CROSS-REFERENCE TO RELATED APPLICATIONS

This application claims priority to and benefits of Korean Patent Application No. 10-2023-0033642 under 35 U.S.C. § 119, filed in the Korean Intellectual Property Office on Mar. 15, 2023, the entire contents of which are incorporated herein by reference.

### BACKGROUND

### 1. Technical Field

The disclosure herein relates to a display device, and, to a display device including a color filter panel.

### 2. Description of the Related Art

Various multimedia display devices such as a television, a mobile phone, a tablet computer or a game machine include a display panel and a color filter panel for providing image information to a user.

The display panel may include light emitting elements and pixel circuits for driving the light emitting elements. Source light provided from the light emitting elements of the display panel may be converted into light of various colors by a light control unit using quantum dots.

The color filter panel improves the color purity and light extraction efficiency of the light of various colors provided from the display panel, and reduces the reflection of external light. A display device with high resolution is currently required, and thus it is necessary to study the structure of the color filter panel for improving the light extraction efficiency.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a display device including a color filer panel with improved light extraction efficiency.

An embodiment provides a display device that may include a display panel including a light emitting element layer and a light control layer disposed on the light emitting element layer; and a color filter panel disposed on the display panel, wherein the color filter panel may include a base layer; a color filter layer disposed below the base layer; a low refractive layer disposed below the color filter layer; and a spacer disposed between the color filter layer and the low refractive layer, wherein sides of the spacer are covered by the low refractive layer.

In an embodiment, the display device may include a pixel area and a peripheral area surrounding the pixel area, wherein the spacer surrounds the pixel area in a plan view.

In an embodiment, the display device may further include a filling layer disposed between the display panel and the color filter panel, wherein the color filter panel may include an opening defined by the spacer, and the filling layer is disposed in the opening of the color filter panel.

In an embodiment, the low refractive layer may include an inorganic layer.

In an embodiment, the inorganic layer may include at least one of silicon oxide, silicon nitride, and silicon oxynitride.

In an embodiment, a refractive index of the inorganic layer may be in a range of about 1.3 to about 1.45.

In an embodiment, the low refractive layer may include an organic layer disposed below the color filter layer and an inorganic layer disposed below the organic layer.

In an embodiment, the organic layer may include hollow particles or voids, and the inorganic layer may include at least one of silicon oxide, silicon nitride, and silicon oxynitride.

In an embodiment, a refractive index of the organic layer may be in a range of about 1.15 to about 1.35, and a refractive index of the inorganic layer may be in a range of about 1.3 to about 1.45.

In an embodiment, the color filter panel may further include a reflection layer disposed at sides of the spacer with the low refractive layer disposed between the spacer and the reflection layer, and the reflection layer may include a metal.

In an embodiment, the display device may include a first pixel area, and a second pixel area spaced apart from the first pixel area, wherein the spacer may include a first spacer and a second spacer spaced apart from the first spacer, wherein the first spacer surrounds the first pixel area, and the second spacer surrounds the second pixel area in a plan view.

In an embodiment, a display device may include a display panel including a light emitting element layer and a light control layer disposed on the light emitting element layer; and a color filter panel disposed on the display panel, wherein the color filter panel may include a base layer; a color filter layer disposed below the base layer; a spacer disposed below the color filter layer; and a reflection layer covering sides of the spacer.

In an embodiment the reflection layer may include a metal.

In an embodiment, the display device may include a pixel area and a peripheral area surrounding the pixel area, wherein the spacer surrounds the pixel area in a plan view.

In an embodiment, the display device may further include a filling layer disposed between the display panel and the color filter panel, wherein the color filter panel may include an opening defined by the spacer, and the filling layer is disposed in the opening of the color filter panel.

In an embodiment, the color filter panel may further include a low refractive layer disposed below the color filter layer and disposed between the spacer and the reflection layer. In an embodiment, the low refractive layer may include an inorganic layer.

In an embodiment, the inorganic layer may include at least one of silicon oxide, silicon nitride, and silicon, and a refractive index of the inorganic layer may be in a range of about 1.3 to about 1.45.

In an embodiment, the low refractive layer may include an organic layer disposed below the color filter layer and an inorganic layer disposed below the organic layer.

In an embodiment, the organic layer may include hollow particles or voids, and a refractive index of the organic layer may be in a range of about 1.15 to about 1.35, and wherein the inorganic layer may include at least one of silicon oxide, silicon nitride, and silicon oxynitride, and a refractive index of the inorganic layer may be in a range of about 1.3 to about 1.45.

In an embodiment, the display device may include a first pixel area, and a second pixel area spaced apart from the first pixel area, wherein the spacer may include a first spacer and a second spacer spaced apart from the first spacer, wherein the first spacer surrounds the first pixel area, and the second spacer surrounds the second pixel area in a plan view.

In an embodiment, a display device may include a pixel area and a peripheral area surrounding the pixel area; a display panel including a light emitting element layer and a light control layer disposed on the light emitting element layer; and a color filter panel disposed on the display panel, wherein the color filter panel may include a base layer; a color filter layer disposed below the base layer; a spacer disposed below the color filter layer; and a low refractive layer disposed below the color filter layer, wherein the spacer surrounds the pixel area in a plan view.

In an embodiment, the spacer may be disposed between the color filter layer and the low refractive layer, and the low refractive layer may cover sides of the spacer.

In an embodiment, the display device may further include a filling layer disposed between the display panel and the color filter panel, wherein the color filter panel may include an opening defined by the spacer, and the filling layer is disposed in the opening of the color filter panel.

In an embodiment, the color filter panel may further include a reflection layer disposed at sides of the spacer with the low refractive layer disposed between the spacer and the reflection layer, wherein the reflection layer may include a metal.

In an embodiment, the pixel area may include a first pixel area and a second pixel area spaced apart from the first pixel area, and the spacer may include a first spacer and a second spacer spaced apart from the first spacer, wherein the first spacer surrounds the first pixel area, and the second spacer surrounds the second pixel area in a plan view.

### BRIEF DESCRIPTION OF THE DRAWINGS

The accompanying drawings are included to provide a further understanding of the disclosure, and are incorporated in and constitute a part of this specification. The drawings illustrate embodiments and, together with the description, serve to explain principles of the disclosure. In the drawings:

FIG. 1A is a schematic perspective view of a display device according to an embodiment;

FIG. 1B is a schematic cross-sectional view of a display device according to an embodiment;

FIG. 2 is a schematic plan view of a display panel according to an embodiment;

FIG. 3 is schematic diagram of an equivalent circuit of a pixel according to an embodiment;

FIG. 4 is an enlarged schematic plan view of a display area according to an embodiment;

FIGS. 5 to 8 respectively illustrate schematic cross-sectional views of portions of a display device according to an embodiment; and

FIGS. 9A and 9B respectively are schematic cross-sectional views of light emitting layers according to an embodiment.

### DETAILED DESCRIPTION OF THE EMBODIMENTS

The disclosure may be variously modified and realized in various forms, and thus embodiments will be included in the drawings and described in detail hereinafter. However, it will be understood that the disclosure is not intended to be limited to the forms set forth herein, and all changes, equivalents, and substitutions included in the technical scope and spirit of the disclosure are included.

As used herein, the singular forms, “a,” “an,” and “the” are intended to include the plural forms as well, unless the context clearly indicates otherwise.

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be further understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be understood that when an element or layer is referred to as being “on” or, “connected to”, or “coupled to” another element or layer, it means that the element may be directly disposed on/connected to/coupled to the other element, or a third element or other elements may be disposed therebetween.

In the specification, terms such as “below,” “lower,” “above,” “upper,” and the like are used to describe the relationship of the configurations shown in the drawings. The terms are used as a relative concept and are described with reference to the direction indicated in the drawings.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

In the specification, being “disposed on” may not only include the case of being disposed on an upper portion of any one member but also the case of being disposed on a lower portion thereof

On the other hand, being “directly disposed” means that there is no layer, film, region, plate or the like added between a portion of a layer, a film, a region, a plate, or the like and other portions. For example, being “directly disposed” may mean being disposed without additional members such as an adhesive member between two layers or two members.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification, terms such as first, second, and the like may be used to describe various components, but these components should not be limited by the terms. The terms are only used to distinguish one element from another. For example, a first element could be termed a second element, and, similarly, a second element could be termed a first element, without departing from the scope of example embodiments of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Like reference numerals in the drawings refer to like elements. In the drawings, the thickness and the ratio and the dimension of the element are exaggerated for effective description of the technical contents.

Hereinafter, a display device and a manufacturing method thereof according to an embodiment will be described with reference to the drawings.

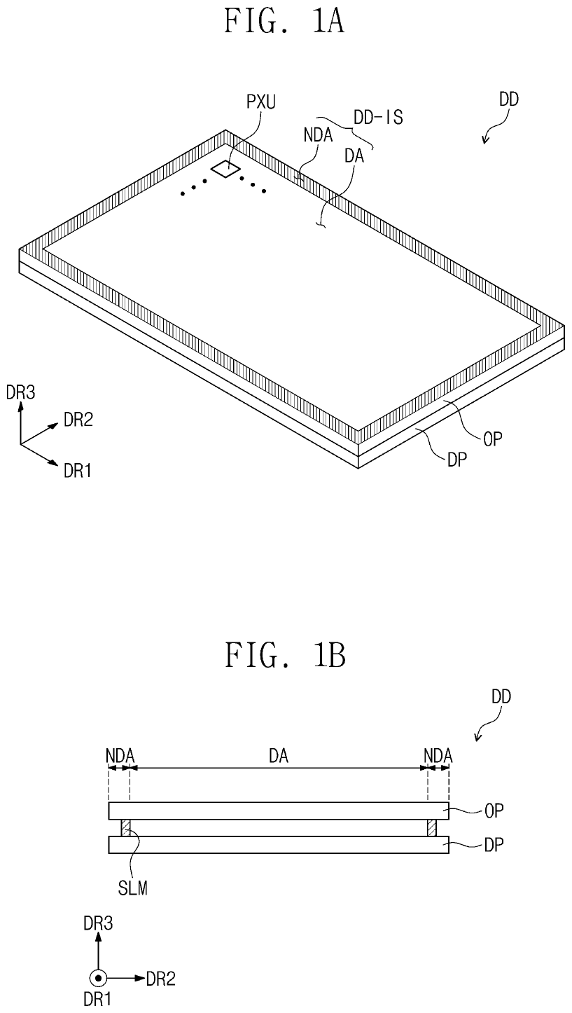

FIG. 1A is a schematic perspective view of a display device DD according to an embodiment. FIG. 1B is a schematic cross-sectional view of the display device DD according to an embodiment.

Referring to FIG. 1A, the display device DD may display an image through a display surface DD-IS. The display surface DD-IS may be parallel to a surface defined by a first direction DR1 and a second direction DR2. The top surface of a member disposed on the uppermost side of the display device DD in a third direction DR3 may be defined as the display surface DD-IS.

The normal direction of the display area DD-IS, namely, a thickness direction of the display device DD, may be indicated by a third direction DR3. The front surfaces (or top surfaces) and the rear surfaces (or bottom surfaces) of respective layers or units, which will be described hereinafter, are divided by the third direction DR3.

The display device DD may include a display area DA and a non-display area NDA. The display area DA may include unit pixels PXU disposed therein and the non-display area NDA does not include the unit pixels PXU. The non-active area NDA may be defined along the edge of the display surface DD-IS. The non-display area NDA may surround the display area DA. In an embodiment, the non-display area NDA may be omitted or disposed only at one side or a side of the display area DA. FIG. 1A illustrates an example planar display device DD, but the display device DD may have a curved shape, or be foldable or rollable, or be slidable from a housing.

The unit pixels PXU shown in FIG. 1A may define pixel rows and pixel columns. A unit pixel PXU is a minimum repeatable unit, and may include at least one pixel. The unit pixels PXU may include pixels providing light of different colors.

Referring to FIG. 1B, the display device DD may include a display panel DP, and a color filter panel OP facing and spaced apart from the display panel DP. The display panel DP may be referred to as a bottom display board, and the color filter panel OP may be referred to as a top display substrate. A prescribed cell gap may be provided between the display panel DP and the color filter panel OP. The cell gap may be maintained by a sealing member SLM combining the display panel DP and the color filter panel OP. The sealing member SLM may include a binder resin and inorganic fillers mixed with the binder resin. The sealing member SLM may include other additive agents. The additive agents may include amine-based curing agents and photo-initiators. The additive agents may further include silane-based additive agents and acrylic-based additive agents. The sealing member SLM may also include inorganic material such as frit.

In each of the display panel DP and the color filter panel OP, a display area DA and a non-display area NDA may be defined as the same as the display area DA and the non-display area NDA of the display device DD. Hereinafter, the display area DA of the display device DD may means the display area DA of each of the display panel DP and the color filter panel OP, and the non-display area NDA of the display device DD may mean the non-display area NDA of each of the display panel DP and the color filter panel OP.

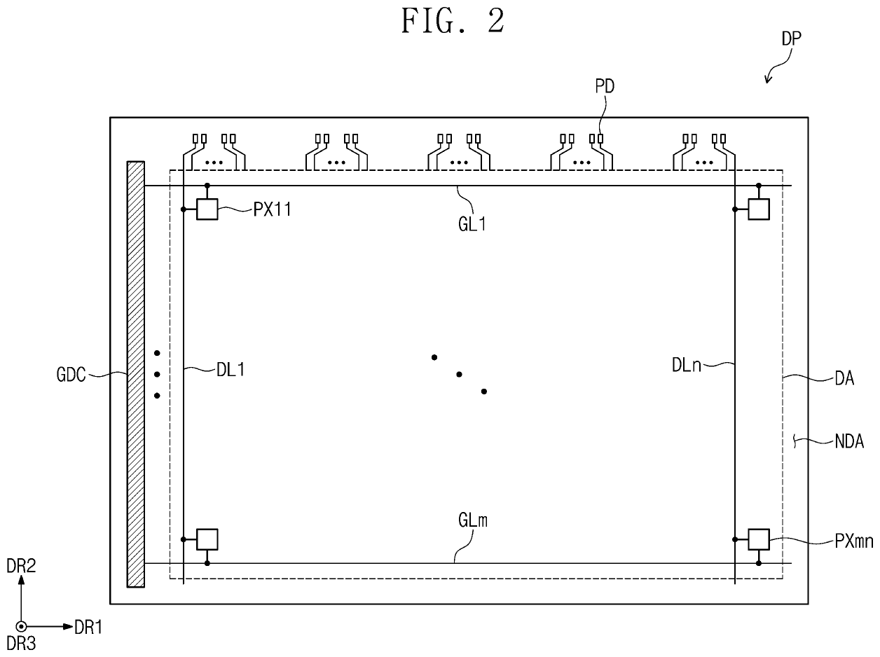

FIG. 2 is a schematic plan view of the display panel DP according to an embodiment.

FIG. 2 illustrates a planar arrangement of signal lines GL1 to GLm, DL1 to DLn and pixels PX11 to PXmn. The signal lines GL1 to GLm, DL1 to DLn may include gate lines GL1 to GLm and data lines DL1 to DLn.

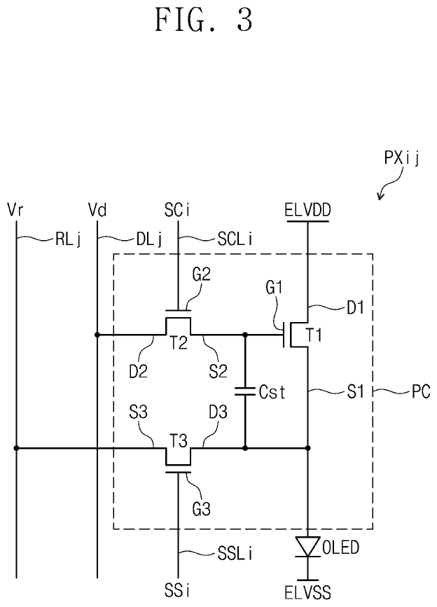

Each of the pixels PX11 to PXnm may be connected to a corresponding gate line among the gate lines GL1 to GLn, and a corresponding data line among the data lines DL1 to DLm. Each of the pixels PX11 to PXnm may include a pixel driving circuit and a light emitting element. According to the configuration of the pixel driving circuit of the pixels PX11 to PXmn, more various kinds of signal lines may be provided to the display panel DP. For example, each of the gate lines GL1 to GLm may include a corresponding scan line SCLi (see FIG. 3) and a corresponding sensing line SSLi (see FIG. 3).

A gate driving circuit GDC may be integrated to the display panel DP through an oxide silicon gate driver circuit (OSG) process or an amorphous silicon gate driver circuit (ASG) process. The gate driving circuit GDC connected to the gate lines GL1 to GLm may be disposed at one side or a side of the non-display area NDA in the first direction DR1. Pads PD connected to the terminals of the data lines DL1 to DLn may be disposed at one side or a side of the non-display area NDA in the second direction DR2.

FIG. 3 is a schematic diagram of an equivalent circuit of a pixel PXij according to an embodiment.

FIG. 3 shows an example pixel PXij connected to an i-th scan line SCLi, an i-th sensing line SSLi, a j-th data line DLj, and a j-th reference line RLj. The pixel PXij may include a pixel circuit PC and a light emitting element OLED connected to the pixel circuit PC. The pixel circuit PC may include transistors T1, T2, T3 and a capacitor Cst. The transistors T1, T2, T3 may be provided through a Low Temperature Polycrystalline Silicon (LTLPS) process or a Low Temperature Polycrystalline Oxide (LTPO) process. Hereinafter, the transistors T1, T2, T3 may be described as N-type transistors, but at least one transistor may be implemented with a P-type transistor.

In the embodiment, the example pixel circuit PC including the first transistor T1, the second transistor T2, the third transistor T3, and the capacitor Cst is shown, but the pixel circuit PC is not limited thereto. The first transistor T1 may be a driving transistor, the second transistor T2 may be a switching transistor, and the third transistor T3 may be a sensing transistor. The pixel circuit PC may further include an additional transistor or an additional capacitor.

The light emitting element OLED may be an organic or inorganic light emitting element including an anode (first electrode) and a cathode (second electrode). The anode of the light emitting element OLED may receive a first voltage ELVDD through the first transistor T1, and the cathode of the light emitting element OLED may receive a second voltage ELVSS. The light emitting element OLED may receive the first voltage ELVDD and the second voltage ELVSS to emit light.

The first transistor T1 may include a drain D1 to receive the first voltage ELVDD, a source S1 connected to the anode of the light emitting element OLED, and a gate G1 connected to the capacitor Cst. The first transistor T1 may control a driving current flowing from the first voltage ELVDD to the light emitting element OLED in correspondence to the voltage stored in the capacitor Cst.

The second transistor T2 may include a drain D2 connected to a j-th data line DLj, a source S2 connected to the capacitor Cst, and a gate G2 receiving the first scan signal SCi. The j-th data line DLj may receive a data voltage Vd. The second transistor T2 may provide the data voltage Vd to the first transistor T1 in response to the i-th first scan signal SCi.

The third transistor T3 may include a source S3 connected to a j-th reference line RLj, a drain D3 connected to the anode of the light emitting element OLED, and a gate G3 receiving the i-th second scan signal SSi. The j-th reference line RLj may receive a reference voltage Vr. The third transistor T3 may initialize the capacitor Cst and the anode of the light emitting element OLED.

The capacitor Cst may store a voltage corresponding to the difference between the voltage received from the second transistor T2 and the first voltage ELVDD. The capacitor Cst may be connected to the gate G1 of the first transistor T1 and the anode of the light emitting element OLED.

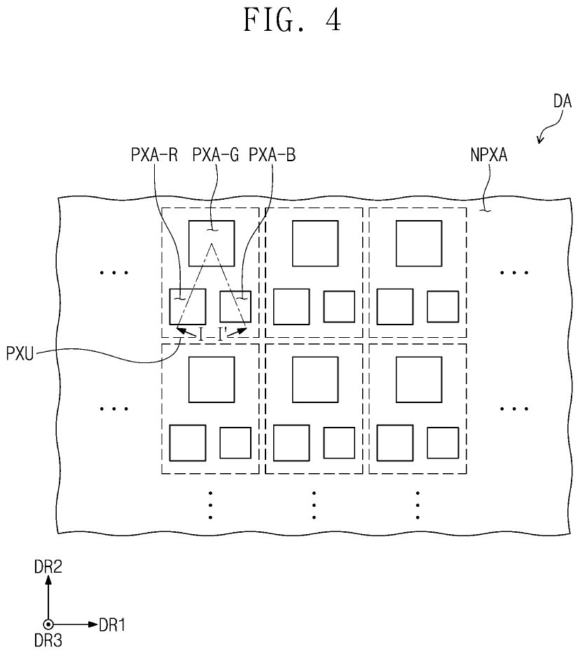

FIG. 4 is an enlarged schematic plan view of the display area DA according to an embodiment.

As shown in FIG. 4, the unit pixels PXU may be arranged or disposed in the first direction DR1 and the second direction DR2. In the embodiment, the unit pixels PXU may include a first pixel, a second pixel, and a third pixel that emit light of different colors. The first pixel, the second pixel, and the third pixel may respectively output red light, green light, and blue light. FIG. 4 shows a first pixel area PXA-R, a second pixel area PXA-G, and a third pixel area PXA-B in representative of the first pixel, the second pixel, and the third pixel, respectively. The first pixel area PXA-R may be an area from which the light generated from the first pixel is provided externally, the second pixel area PXA-G may be an area from which the light from the second pixel is provided externally, and the third pixel area PXA-B may be an area from which the light from the third pixel is provided externally.

A peripheral area NPXA may be disposed in a form of surrounding the first pixel area PXA-R, the second pixel area PXA-G, and the third pixel area PXA-B. The peripheral area NPXA may be disposed between the first pixel area PXA-R, the second pixel area PXA-G, and the third pixel area PXA-B. The peripheral area NPXA may set the boundaries of the first to third pixel regions PXA-R, PXA-G and PXA-B, thereby preventing color mixture between the first to third pixel regions PXA-R, PXA-G and PXA-B.

Referring to FIG. 4, the first pixel area PXA-R may be disposed in the same row as the third pixel area PXA-G, and the second pixel area PXA-G may be disposed in a different row from the first pixel area PXA-R and the third pixel area PXA-B. The second pixel area PXA-G may have the largest area, and the third pixel area PXA-B may have the smallest area, but the embodiment is not limited thereto. In the embodiment, the first pixel area PXA-R, the second pixel area PXA-G, and the third pixel area PXA-B are shown as having a substantially square shape, but this is an example and the embodiment is not limited thereto.

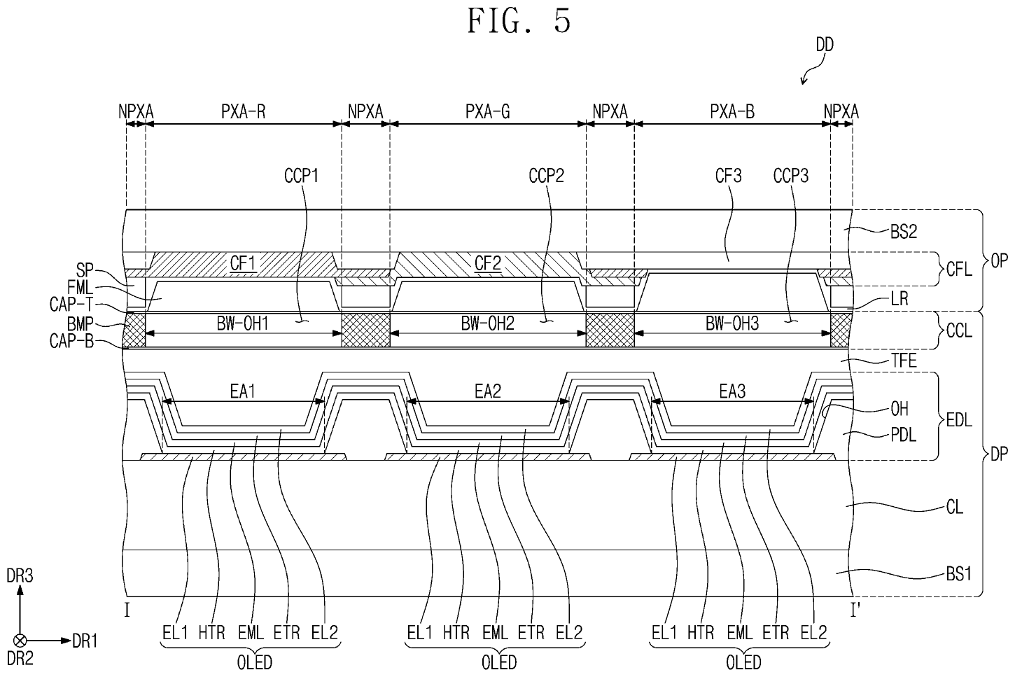

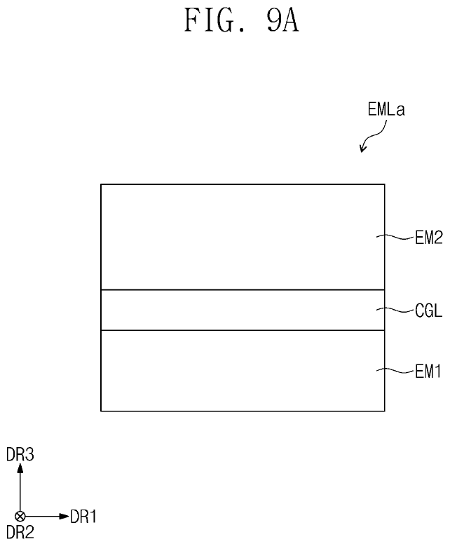

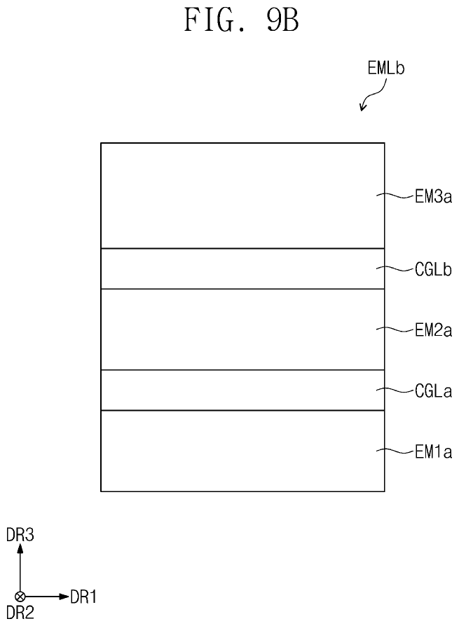

FIGS. 5 to 8 respectively illustrate schematic cross-sectional views of portions of the display device DD according to an embodiment. FIGS. 9A and 9B respectively are schematic cross-sectional views of light emitting layers EMLa, EMLb according to an embodiment.

FIGS. 5 to 8 each show a cross section corresponding to line I-I′ of FIG. 4, but this is an example and the embodiment is not limited thereto. In FIGS. 5 to 8, example cross sections of the first to third pixel areas PXA-R, PXA-G, PXA-B are shown.

The display panel DP may include a first base layer BS1, a circuit layer CL, a light emitting element layer EDL, a thin film encapsulation layer, and a light control layer CCL. The circuit layer CL may be disposed on the first base layer BS1. The light emitting element layer EDL may be disposed on the circuit layer CL. The thin film encapsulation layer TFE may be disposed on the light emitting element layer EDL to encapsulate the light emitting element layer EDL. The light control layer CCL may be disposed on the thin film encapsulation layer TFE to convert source light from the light emitting element layer EL to light of other wavelengths.

The first base layer BS1 may include glass or a synthetic resin film. The synthetic resin layer may include a thermosetting resin. For example, the synthetic resin layer may be a polyimide-based resin layer, but the material is not particularly limited. The synthetic resin layer may include at least one of an acrylic-based resin, a meta-acrylic-based resin, polyisoprene, a vinyl-based resin, an epoxy-based resin, a urethane-based resin, a cellulose-based resin, a siloxane-based resin, a polyamide-based resin, or a parylene-based resin. Besides, the first base layer BS1 may include a glass substrate, a metal substrate, or an organic/inorganic composite material substrate, etc.

The circuit layer CL may be disposed on the first base layer BS1. The circuit layer CL may include an insulation layer, a semiconductor pattern, a conductive pattern, signal lines or the like within the spirit and the scope of the disclosure. The insulation layer, a semiconductor layer, and a conductive layer may be provided on the first base layer BS1 through methods such as coating or vapor deposition, and, the insulation layer, the semiconductor layer, and the conductive layer may be selectively patterned by repeated photolithography processes. Thereafter, the semiconductor pattern, the conductive pattern, and the signal lines may be provided. The circuit layer CL may include a transistor, a buffer layer, and insulation layers.

The light-emitting element layer EDL may be disposed on the circuit layer CL, and include a light emitting element OLED and a pixel definition layer PDL.

The light emitting element OLED may include a first electrode EL1, a second electrode EL2 opposite the first electrode EL1, and the light emitting layer EML disposed between the first electrode EL1 and the second electrode EL2. The light emitting layer EML included in the light emitting element OLED may include, as a light emitting material, an organic light emitting material or quantum dots. The light emitting element OLED may further include a hole transport area HTR and/or an electron transport area ETR. Although not shown, the light emitting element OLED may further include a capping layer (not shown) disposed above the second electrode EL2.

The pixel definition layer PDL may be disposed on the circuit layer CL, and cover a portion of the first electrode EL1. An emission opening OH may be defined in the pixel definition layer PDL. The emission opening OH in the pixel definition layer PDL may expose at least a portion of the first electrode EL1. First to third light emitting areas EA1, EA2, EA3 may be defined in correspondence to the portion of the first electrode EL1 exposed by the emission opening OH in the pixel definition layer PDL. The first light emitting area EA1, the second light emitting area EA2, and the third light emitting area EA3 may respectively correspond to the first pixel area PXA-R, the second pixel area PXA-G, and the third pixel area PXA-B. The area other than the first to third light emitting areas EA1, EA2, and EA3 may be defined as a non-light emitting area.

Here, the “correspond to” means that, when viewed from the thickness direction DR3 of the display panel DD, two components overlap and are not limited to have the same area. The first to third light emitting areas EA1, EA2, EA3 may overlap the first to third pixel areas PXA-R, PXA-G, PXA-B. When viewed in a plan view, the area of the first to third pixel areas PXA-R, PXA-G, PXA-B may be respectively greater than the area of the first to third light emitting areas EA1, EA2, EA3 divided by the pixel definition layer PDL. This is an example, and the embodiment is not limited thereto. The area of the pixel areas PXA-R, PXA-G, PXA-B may be substantially the same as that of the light emitting areas EA1, EA2, EA3 divided by the pixel definition layer PDL.

The first electrode EL1 may be disposed on the circuit layer CL. The first electrode EL1 may be an anode or a cathode. The first electrode EL1 may be a pixel electrode. The first electrode EL1 may be a transparent electrode, a semi-transparent electrode, or a reflective electrode.

The hole transport area HTR may be disposed on the first electrode EL1. The hole transport area HTR may be commonly disposed in the first to third light emitting areas EA1, EA2, EA3, and the non-light emitting area. The common layer such as the hole transport area HTR may be disposed to overlap the unit pixels PXU in the display area DA in FIG. 4. However, the embodiment is not limited thereto, and the hole transport area HTR may be separately disposed in correspondence to each of the first to third light emitting areas EA1, EA2, EA3. The hole transport area HTR ma include at least one of a hole transport layer, a hole injection layer, and an electron blocking layer.

The light emitting layer EML may be disposed on the hole transport area HTR. The light emitting layer EML may be commonly disposed in the first to third light emitting areas EA1, EA2, EA3 and the non-light emitting area. The light emitting element EML may be disposed to overlap all of the hole transport area HTR and the electron transport area ETR. However, the embodiment is not limited thereto, and, in an embodiment, the light emitting layer EML may be disposed in the emission opening OH. In other words, the light emitting layer EML may be separately disposed so as to correspond to each of the first to third light emitting areas EA1, EA2, EA3 divided by the pixel definition layer PDL.

The light emitting layer EML may generate source light. In an embodiment, the light emitting layer EML may emit blue light. In the display device DD of an embodiment, the blue light may be the source light. In case that separately disposed to correspond to the first to third light emitting areas EA1, EA2, EA3, the light emitting layer EML may emit the blue light entirely or emit light of different wavelengths in the first to third light emitting areas EA1, EA2, EA3.

The light emitting layer EML may have a single layer formed from a single material, a single layer formed from different materials, or a multi-layer structure having layers formed from different materials. The light emitting layer EML may include a fluorescent material or phosphorescent material. The light emitting layer EML in the light emitting element in an embodiment may include light emitting materials such as organic light emitting elements, a metal organic complex, quantum dots, or the like within the spirit and the scope of the disclosure.

FIGS. 9A and 9B are schematic cross-sectional views showing example cases where the above-described light emitting layer EML (see FIGS. 5 to 8) has a multi-layer structure.

Referring to FIG. 9A, a light emitting layer EMLa may include a first light emitting layer EM1, a charge generation layer CGL, and a second light emitting layer EM2 that are sequentially laminated along the third direction DR3. The first light emitting layer EM1 and the second light emitting layer EM2 may emit different colors. For example, the first light emitting layer EM1 may emit blue light, and the second light emitting layer EM2 may emit green light.

The charge generation layer CGL may be disposed between the first light emitting layer EM1 and the second light emitting layer EM2. The charge generation layer CGL may supply electrons or holes to each of the first light emitting layer EM1 and the second light emitting layer EM2 to improve the emission efficiency.

Referring to FIG. 9B, a light emitting layer EMLb may include a first light emitting layer EM1a, a first charge generation layer CGLa, a second light emitting layer EM2a, a second charge generation layer CGLb, and a third light emitting layer EM3a that are sequentially laminated along the third direction DR3.

One of the first light emitting part EM1a, the second light emitting layer EM2a, or the third light emitting layer EM3a may emit color light different from the other two. For example, the first light emitting layer EM1a and the third light emitting layer EM3a may emit the same color light, and the second light emitting layer EM2a may emit color light different from that generated by the first light emitting layer EM1a. For example, the first light emitting layer EM1a and the third light emitting layer EM3a emit blue light, and the second light emitting layer EM2a may emit green light.

The first charge generation layer CGLa may be disposed between the first light emitting layer EM1a and the second light emitting layer EM2a. The second charge generation layer CGLb may be disposed between the second light emitting layer EM2a and the third light emitting layer EM3a. The first charge generation layer CGLa may supply electrons or holes to each of the first light emitting layer EM1a and the second light emitting layer EM2a to improve the emission efficiency. The second charge generation layer CGLb may supply electrons or holes to each of the second light emitting layer EM2a and the third light emitting layer EM3a to improve the emission efficiency.

The electronic transport area ETR may be disposed on the light emitting layer EML. The electron transport area ETR may include at least one of an electron injection layer, an electron transport layer, and a hole blocking layer. The electron transport area ETR may be disposed as a common layer so as to overlap all of the first to third light emitting areas EA1, EA2, EA3 and the pixel definition layer PDL. However, the embodiment is not limited thereto, and the hole transport area ETR may be separately disposed in each of the first to third light emitting areas EA1, EA2, EA3.

The second electrode EL2 may be disposed on the electron transport area ETR. The second electrode EL2 may be a common electrode. The second electrode EL2 may be a cathode or an anode, but the embodiment is not limited thereto. For example, In case that the first electrode EL1 is an anode, the second electrode EL2 may be a cathode, and vice versa. The second electrode EL2 may be a transparent electrode, a semi-transparent electrode, or a reflective electrode.

The thin film encapsulation layer TFE may be disposed on the second electrode EL2. By way of example, in case that the light emitting element OLED may include a capping layer (not shown), the thin film encapsulation layer TFE may be disposed on the capping layer (not shown). The thin film encapsulation layer TFE may serve to protect the light emitting layer EDL from moisture and oxygen, and prevent foreign matters such as dust from being introduced.

The thin film encapsulation layer TFE may include at least one inorganic layer. The inorganic material may include at least any one of silicon nitride, silicon oxynitride, silicon oxide, titanium oxide, or aluminum oxide. The thin film encapsulation layer TFE may include at least one organic layer. The organic layer may include organic polymer materials provided from an acrylic-based resin or the like within the spirit and the scope of the disclosure. However, this is an example, and the embodiment is not limited thereto.

The light control layer CCL may be disposed on the thin film encapsulation layer TFE. The light control layer CCL may be disposed on the top portion of the display panel DP. However, this is an example, and the embodiment is not limited thereto. For example, the display panel DP of an embodiment may further include an adhesive layer or other functional layers disposed on the top of the light control layer CCL.

The light control layer CCL may include a division pattern BMP and light control units (or parts) CCP1, CCP2, CCP3. The division pattern BMP in a plan view may overlap the peripheral area NPXA. The light control units CCP1, CCP2, CCP3 included in the light control layer CCL may be spaced apart from each other. The light control units CCP1, CCP2, and CCP3 may be spaced apart from each other by the division pattern BMP. The light control units CCP1, CCP2, and CCP3 may be disposed within openings BW-OH1, BW-OH2, BW-OH3 defined in the division pattern BMP. However, the embodiment is not limited thereto. At least portions of the edges of the light control units CCP1, CCP2, CCP3 may overlap the division pattern BMP.

The division pattern BMP may include a material having the transmissivity of a prescribed value or smaller. For example, the division pattern BMP may include a light blocking material, such as a black coloring agent. The division pattern BMP may include a black dye or a black pigment mixed in the base resin. The black coloring agent may include, for example, carbon black, a metal such as chromium, or an oxide thereof. The division pattern DMP may include at least one of propylene glycol methyl ether acetate), 3-methoxy-n-butyl acetate, acrylate monomer, acrylic monomer, organic pigment, or acrylate ester.

The light control units CCP1, CCP2, CCP3 may be portions of converting the wavelength of the source light provided from the light emitting element layer EDL, or transmitting the provided source light without a wavelength change. The light control units CCP1, CCP2, and CCP3 may be provided through an inkjet process. Liquid ink compositions are provided into the openings BW-OH1, BW-OH2, BW-OH3, and the provided ink compositions are polymerized through a heat curing process or a light curing process to provide the light control units CCP1, CCP2, and CCP3. For example, the shapes of the openings BW-OH1, BW-OH2, BW-OH3 may respectively correspond to those of the light control units CCP1, CCP2, and CCP3

The light control layer CCL may include the first light control unit CCP1 including first quantum dots to convert first color light provided from the light emitting element OLED into second color light, a second light control unit CCP2 including second quantum dots to convert the first color light into third color light, and a third light control unit CCP3 to transmit the first color light. The first light control unit CCP1 may provide red light as the second color light, and the second light control unit CCP2 may provide green light as the third color light. The third light control unit CCP3 may transmit blue light as the first color light provided from the light emitting element OLED. For example, the first quantum dots may be red quantum dots, and the second quantum dots may be green quantum dots.

A quantum dot may mean a crystal of a semiconductor compound. As the size of the quantum dot or an atomic ratio in the quantum dot is adjusted, the energy band gap may be adjusted and thus light of various wavelength bands may be obtained. For example, the diameter of the quantum dot may be in a range of about 1 nm to about 10 nm. Accordingly, quantum dots of different sizes or different atomic ratios may be used to implement a light emitting element that emits light of various wavelengths. By way of example, the quantum dot may be implemented to emit light of a red, green, or blue color. The quantum dot may be constituted to emit white light by combining light of various colors.

The quantum dot may be synthesized through a wet chemical process, a metal organic chemical vapor deposition (MOCVD) process, a molecular beam epitaxy (MBE) process, or a process similar thereto. The wet chemical process is a method for mixing an organic solvent with a precursor material and growing a quantum dot particle crystal. In case that the crystal is grown, the organic solvent may naturally serve as a dispersing agent coordinated to the quantum dot crystal surface, and adjust the growth of the crystal. Therefore, the wet chemical process may control the growth of the quantum dot particle through processes of an easier and lower cost than vapor deposition methods such as the MOCVD, MBE or the like within the spirit and the scope of the disclosure.

The quantum dot may have a single structure in which elements included in the quantum dot have uniform concentrations or a core-shell dual structure. For example, the material in the core and the material in the shell may be different from each other. The shell of the quantum dot may serve as a protection layer for preventing the core from being chemically modified to maintain the semiconductor characteristics and/or a filling layer for giving the electrophoretic characteristics to the quantum dot. The shell may be a single layer or a multilayer. The core-shell structure may have a concentration gradient that the concentration of the elements present in the shell becomes lower toward the core.

The core of the quantum dot may be selected from among a group II-VI compound, a group III-VI compound, a group I-III-VI compound, a group III-V compound, a group III-II-V compound, a group IV-VI compound, a group IV element, a group IV compound, or a combination thereof.

The group II-VI compound may be selected from a group consisting of: a binary compound selected from a group consisting of CdSe, CdTe, ZnS, ZnSe, ZnTe, ZnO, HgS, HgSe, HgTe, MgSe, MgS, and a mixture thereof; a ternary compound selected from a group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSc, HgZnTe, MgZnSe, MgZnS, and a mixture thereof; or a quaternary compound selected from a group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The group III-VI compound may include: a binary compound such as In₂S₃, In₂Se₃ or the like, a ternary compound such as InGaS₃, InGaSe₃ or the like, or an arbitrary combination thereof.

The group I-III-VI compound may be selected from among: a ternary compound selected from a group consisting of AgInS, AgInS₂, CuInS, CuInS₂, AgGaS₂, CuGaS₂ CuGaO₂, AgGaO₂, AgAlO₂ and a mixture thereof; or a quaternary compound among AgInGaS₂, CuInGaS₂ or the like within the spirit and the scope of the disclosure.

The group III-V compound may include one selected from a group consisting of: a binary compound selected from a group consisting of GaN, GaP, GaAs, GaSb, AlN, AlP, AlAs, AlSb, InN, InP, InAs, InSb, and a mixture thereof; a ternary compound selected from a group consisting of GaNP, GaNAs, GaNSb, GaPAs, GaPSb, AlNP, AlNAs, AlNSb, AlPAS, AlPSb, InNP, InNAs, InNSb, InPAs, InPSb, GaAlNP, and a mixture thereof; or a quaternary compound selected from a group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. On the other hand, the group III-V compound may further include a group II metal. For example, InZnP or the like may be selected as the group III-II-V compound.

The group IV-VI compound may be selected from a group consisting of: a binary compound selected from a group consisting of SnS, SnSe, SnTe, PbS, PbSe, PbTe, and a mixture thereof; a ternary compound selected from a group consisting of SnSeS, SnSeTe, SnSTe, PbSeS, PbSeTe, PbSTe, SnPbS, SnPbSe, SnPbTe, and a mixture thereof; or a quaternary compound selected from a group consisting of SnPbSSe, SnPbSeTe, SnPbSTe, and a mixture thereof. The group IV element may be selected from a group consisting of Si, Ge, and a mixture thereof. The Group IV compound may be a binary compound selected from a group consisting of SiC, SiGe, and a mixture thereof.

The group IV element or compound may include: a single-element compound such as Si. Ge or the like' a binary compound such as SiC, SiGe or the like; or an arbitrary combination thereof.

Here, each element included in a multi-element compound such as the binary compound, the ternary compound, and the quaternary compound may be present within a particle at a uniform concentration or a non-uniform concentration. For example, the chemical formula may mean the kinds of the elements included in the compound, and the atomic ratios in the compound may be different. For example, AgInGaS₂ may mean AgInₓGa₁₋ₓS₂, where x is a real number between 0 and 1.

The shell of the quantum dot may include a metal or non-metal oxide, a semiconductor compound, or a combination thereof.

For example, the metal or non-metal oxide may be: a binary compound such as SiO₂, Al₂O₃, TiO2, ZnO, MnO, Mn₂O₃, Mn₃O₄, CuO, FeO, Fe₂O₃, Fe₃O₄, CoO, Co₃O₄, NiO or the like; or a ternary compound such as MgAl₂O₄, CoFe₂O₄, NiFe₂O₄, CoMn₂O₄ or the like, but the embodiment is not limited thereto.

As an example, the semiconductor compound may be CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AlSb or the like, but the embodiment is not limited thereto.

The quantum dot may have a full width of half maximum (FWHM) of an emission wavelength spectrum of about 45 nm or shorter, or about 40 nm or shorter, or about 30 nm or shorter, and in this range, the color purity or color gamut may be improved. Light emitted through such a quantum dot is emitted omnidirectionally, thereby improving the wide viewing angle.

The shape of the quantum dot may be one used in this art and is not particularly limited, but, for example, a spherical, pyramidal, multi-arm, or cubic nano particle, a nano tube, nanowire, nano fiber, or nano-planar particle or the like may be used. It is also to be understood that the shapes disclosed herein include shapes substantial to the shapes disclosed herein.

As described above, the color of light emitted from the quantum dot may be adjusted according to the size of the particle, and accordingly, the quantum dot may have various emission colors such as blue, red, green or the like within the spirit and the scope of the disclosure. As the particle size of the quantum dot is smaller, the shorter wavelength band the emitted light has. For example, for quantum dots having the same core, the particle size of a quantum dot to emit green light may be smaller than that to emit red light. For the quantum dots having the same core, the particle size of a quantum dot to emit blue light may be smaller than that to emit green light. However, the embodiment is not limited thereto, and even for the quantum dots having the same core, the particle size may be adjusted according to a material or the thickness of the shell. In case that the quantum dots have various emission colors such as blue, red, green or the like, the quantum dots having different emission colors may have different core materials.

The light control layer CCL may further include a scattering body. The first light control unit CCP1 may include first quantum dots and a scattering body, the second light control unit CCP2 may include second quantum dots and a scattering body, and the third light control unit CCP3 may not include quantum dots but include a scattering body.

The scattering body may be an inorganic particle. For example, the scattering body may include at least one of TiO₂, ZnO, Al₂O₃, SiO₂, or hollow silica. The scattering body may include one of TiO₂, ZnO, Al₂O₃, SiO₂, or hollow silica, or a mixture of two or more selected from among TiO₂, ZnO, Al₂O₃, SiO₂, or hollow silica.

The first light control unit CCP1, the second light control unit CCP2, and the third light control unit CCP3 each may further include a base resin to disperse the quantum dots and the scattering body. In an embodiment, the first light control unit CCP1 may include the first quantum dots and the scattering body dispersed in the base resin, the second light control unit CCP2 may include the second quantum dots and the scattering body dispersed in the base resin, and the third light control unit CCP3 may include the scattering body dispersed in the base resin.

The base resin is a medium in which the quantum dots and scattering body are dispersed, and may be composed of various resin compositions that are referred to as a binder. For example, the base resin may be an acrylic resin, a urethane resin, a silicone resin, an epoxy resin, or the like within the spirit and the scope of the disclosure. The base resin may be a transparent resin.

The light control layer CCL may further include capping layers CAP-T, CAP-B disposed on at least one of the top or bottom of the light control unit. The capping layers CAP-T, CAP-B may serve to prevent moisture and/or oxygen from being permeated. The capping layers CAP-T, CAP-B may be disposed on the top or bottom of the light control units CCP1, CCP2, CCP3 to prevent the light control units CCP1, CCP2, CCP3 from being exposed to moisture/oxygen.

The capping layers CAP-T, CAP-B may include a bottom capping layer CAP-B adjacent to the thin film encapsulation layer TFE, and a top capping layer CAP-T spaced apart from the thin film encapsulation layer TFE with the bottom capping layer CAP-B, the division pattern BMP, and the light control units CCP1, CCP2, CCP3 interposed therebetween. The top capping layer CAP-T may cover one of the surfaces of the light control units CCP1, CCP2, CCP3 adjacent to the thin film encapsulation layer TFE, the top capping layer CAP-T may cover the other surfaces of the light control units CCP1, CCP2, CCP3 adjacent to a color filter layer CFL of the color filter panel OP. The capping layers CAP-T, CAP-B may cover not only the light control units CCP1, CCP2, CCP3, but also the division pattern BMP.

The capping layers CAP-T, CAP-B each may include at least one inorganic layer. In other words, the capping layers CAP-T, CAP-B each may include inorganic materials. For example, the capping layers CAP-T, CAP-B each may be formed from silicon nitride, aluminum nitride, zirconium nitride, titanium nitride, halfnium nitride, tantalum nitride, silicon oxide, aluminum oxide, titanium oxide, zinc oxide, cerium oxide, or a metal thin film in which a light transmittance is ensured. For example, the bottom capping layer CAP-B may include silicon oxide nitride, and the top capping layer CAP-T may include silicon oxide. However, the embodiment is not limited thereto. The capping layers CAP-T, CAP-B each may further include an organic film. The capping layers CAP-T, CAP-B each may include a single layer or layers.

The color filter panel OP may be disposed on the display panel DP. The color filter panel OP may include a second base layer BS2, the color filter payer CFL, a low refractive layer LR, and a spacer SP. The color filter layer CFL may be disposed below the second base layer BS2. The low refractive layer LR may be disposed below the color filter layer CFL. The spacer SP may be disposed below the color filter layer CFL.

The second base layer BS2 may be a member to provide a base surface above which the color filter layer CFL or the like is disposed. The second base layer BS2 may include glass or a synthetic resin film. The synthetic resin layer may include a thermosetting resin. For example, the synthetic resin layer may be a polyimide-based resin layer, but the material is not particularly limited. The synthetic resin layer may include at least one of an acrylic-based resin, a meta-acrylic-based resin, polyisoprene, a vinyl-based resin, an epoxy-based resin, a urethane-based resin, a cellulose-based resin, a siloxane-based resin, a polyamide-based resin, or a parylene-based resin. Besides, the second base layer BS2 may include a glass substrate, a metal substrate, or an organic/inorganic composite material substrate, etc.

The color filter layer CFL may be disposed below the second base layer BS2. The color filter layer CFL may include color filters CF1, CF2, CF3. The color filter layer CFL may include a first color filter CF1 to transmit the second color light, a second color filter CF2 to transmit the third color light, and a third color filter to transmit the first color light. For example, the first color filter CF1 may be a red color filter, the second color filter CF2 may be a green color filter, and the third color filter CF3 may be a blue color filter. The first color filter CF1 and the second color filter CF2 may be yellow color filters. The first color filter CF1 and the second color filter CF2 may not be divided but may be integral.

The first color filter CF1 may only transmit light in a partial wavelength range of the second color light, namely, light in a central wavelength range to increase the color purity. The second color filter CF2 may only transmit light in a partial wavelength range of the third color light, namely, light in a central wavelength range to increase the color purity. The third color filter CF3 may only transmit light in a partial wavelength range of the third color light, namely, light in a central wavelength range to increase the color purity.

The color filters CF1, CF2, CF3 each may include a polymer photosensitive resin, and a pigment or dye. The first color filter CF1 may include a red pigment or dye, the second color filter CF2 may include a green pigment or dye, and the third color filter CF3 may include a blue pigment or dye. The embodiment is not limited thereto, and the third filter may not include a pigment nor dye. The third color filter CF3 may include the polymer photosensitive resin, but not include the pigment or dye. The third color filter CF3 may be transparent. The third color filter CF3 may a transparent photosensitive resin.

The first to third color filters CF1, CF2, CF3 may be respectively disposed corresponding to the first pixel area PXA-R, the second pixel area PXA-G, and the third pixel area PXA-B. The first to third color filters CF1, CF2, CF3 may be respectively disposed to correspond to the first to third light control units CCP1, CCP2, CCP3.

The color filers CF1, CF2, CF3 may be disposed to overlap the color filters CF1, CF2, CF3 to transmit different color light in correspondence to the peripheral area NPXA disposed between the pixel areas PXA-R, PXA-G, PXA-B. The color filers CF1, CF2, CF3 may be disposed to overlap each other in the third direction DR3 being the thickness direction. The area in which the color filers CF1, CF2, CF3 may be disposed to overlap each other may define the boundaries between the adjacent light emitting areas PXA-R, PXA-G, PXA-B.

When viewed in a plan view, the area of a portion with only the first color filter CF1 disposed therein may be smaller than that of the first control unit CCP1. When viewed in a plan view, the area of a portion with only the second color filter CF2 disposed therein may be smaller than that of the second control unit CCP2. When viewed in a plan view, the area of a portion with only the third color filter CF3 disposed therein may be smaller than that of the third control unit CCP3. Accordingly, the area of the first pixel area PXA-R may be smaller than the area of the first light control unit CCP1, the area of the second pixel area PXA-G may be smaller than the area of the second light control unit CCP2, and the area of the third pixel area PXA-B may be smaller than the area of the third light control unit CCP3.

Unlike what is illustrated in the drawing, the color filter layer CFL may include a light blocking area (not shown) defining the boundaries between the adjacent color filters CF1, CF2, CF3. The light blocking unit (not shown) may be provided with a blue color filter or include an organic shielding material or inorganic shielding material including a black pigment or black dye.

The low refractive layer LR may be disposed below the color filter layer CFL. The low refractive layer LR may be disposed above the light control layer CCL. The low refractive layer LR may be disposed between the light control layer CCL and the color filter layer CFL to increase the light extraction efficiency or may also serve as an optical functional layer to prevent reflective light from being incident into the light control layer CCL or the like within the spirit and the scope of the disclosure. The refractive layer LR may have a smaller refractive index in comparison to an adjacent layer. For example, the refractive index of the refractive layer LE may be about 1.45 or smaller.

The refractive layer LR may include at least one inorganic layer. For example, the low refractive layer LR may be composed of silicon nitride, aluminum nitride, zirconium nitride, titanium nitride, halfnium nitride, tantalum nitride, silicon oxide, aluminum oxide, titanium oxide, zinc oxide, cerium oxide, or silicon oxide nitride, or a metal thin film in which the light transmittance is ensured. However, the embodiment is not limited thereto, and the low refractive layer LR may include an organic film. For example, the low refractive layer LR may be provided including a polymer resin, inorganic particles and the like within the spirit and the scope of the disclosure. The low refractive layer LR may further include hollow particles and/or voids dispersed in the organic film, and the refractive index of the low refractive layer LR may be adjusted by a ratio of the hollow particles and/or voids.

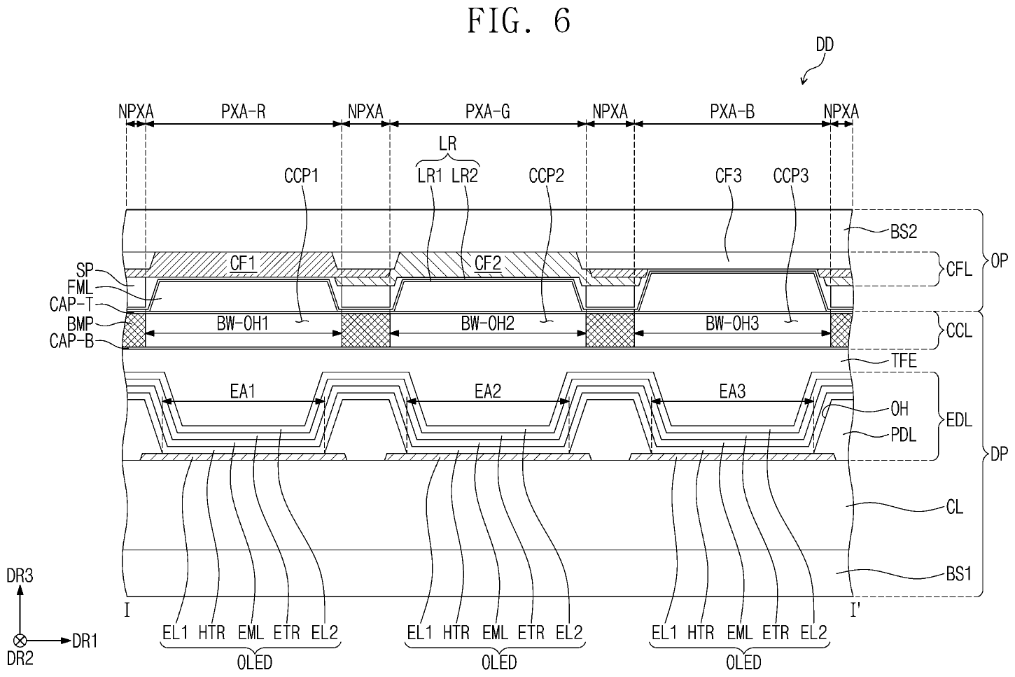

The low refractive layer LR may be provided with a single layer or layers. As shown in FIG. 5, the low refractive layer LR may be constituted with a single layer. As shown in FIG. 6, the low refractive layer LR may be constituted with layers. In case that constituted with the layers, the low refractive layer LR may include a first low refractive layer LR1 and a second low refractive layer LR2. The second low refractive layer LR2 may be disposed below the color filter layer CFL, and the first refractive layer LR1 may be disposed below the second low refractive layer. For example, the first low refractive layer LR1 may be an inorganic layer, and the second low refractive layer LR2 may be an organic layer.

In case of the former, the first refractive layer LR1 may include at least one among silicon oxide, silicon nitride, or silicon oxynitride. The refractive index of the first refractive layer LR1 may be in a range of about 1.3 to about 1.45.

In case of latter, the second refractive layer LR2 may further include hollow particles and/or voids. The refractive index of the second refractive layer LR2 may be in a range of about 1.15 to about 1.35.

In a plan view, the spacer SP may be disposed to overlap an area in which the color filters CF1, CF2, CF3 are disposed. In a plan view, the spacer SP may be disposed not to overlap a portion with only the first color filter CF1 disposed therein, a portion with only the second color filter CF2 disposed therein, and a portion with only the third color filter CF3 disposed therein. By way of example, in a plan view, the spacer SP may be disposed between the first pixel area PXA-R and the second pixel area PXA-G, between the second pixel area PXA-G and the third pixel area PXA-B, and between the first pixel area PXA-R and the third pixel area PXA-B. In a plan view, the spacer SP may surround each of the first pixel area PXA-R, the second pixel area PXA-G, and the third pixel area PXA-B. Any type of the spacer SP is possible, only if, in a plan view, the spacer SP surrounds the first to third pixel areas PXA-R, PXA-G, PXA-B.

The spacer SP is disposed below a portion of the color filter layer CFL, and thus it becomes a type that a protrusion is disposed on the bottom surface of the color filter layer CFL in the third direction DR3, and the spacer SP may correspond to the protrusion.

Only if a material may provide a partition wall, the material of the spacer SP is not limited and any material is possible. For example, the spacer SP may be an organic material. The spacer SP may be a transparent material or a non-transparent material.

Referring to FIGS. 5 and 6, the spacer SP may be disposed between the color filer layer CFL and the low refractive layer LR. The spacer SP may be disposed directly below the color filter layer CFL, and thus the top surface of the spacer SP may contact the color filter layer CFL. The sides of the spacer SP may be covered by the low refractive layer LR. For example, the low refractive layer LR may be disposed at the sides of the spacer SP protruding on the bottom surface of the color filter layer CFL in the third direction DR3.

As the color filter panel OP has such the above-described structure, the side loss may be reduced before the light provided from the display panel DP passes the color filter layer CFL. By way of example, unlike the disclosure, for a color filter panel of the structure without the spacer SP, the side loss may be generated by, of light passing through the light control layer CCL, a light component that heads towards a portion in which the color filters CF1, CF2, overlap each other, but does not head towards a portion with only the first color filter CF1 disposed therein, a portion with only the second color filter CF2 disposed therein, or a portion with only the third color filter CF1 disposed therein. On the contrary, for the color filter panel OP of the above-described structure according to the disclosure, a light component, which heads towards a portion with the color filters CF1, CF2, CF3 overlapping each other, is refracted or reflected by the low refractive layer LR at the sides of the spacer SP to change the path thereof. The path-changed light component may head towards a portion with only the first color filter CF1 disposed therein, a portion with only the second color filter CF2 disposed therein, and a portion with only the third color filter CF3 disposed therein. Accordingly, the light extraction efficiency of the display device DD may be improved.

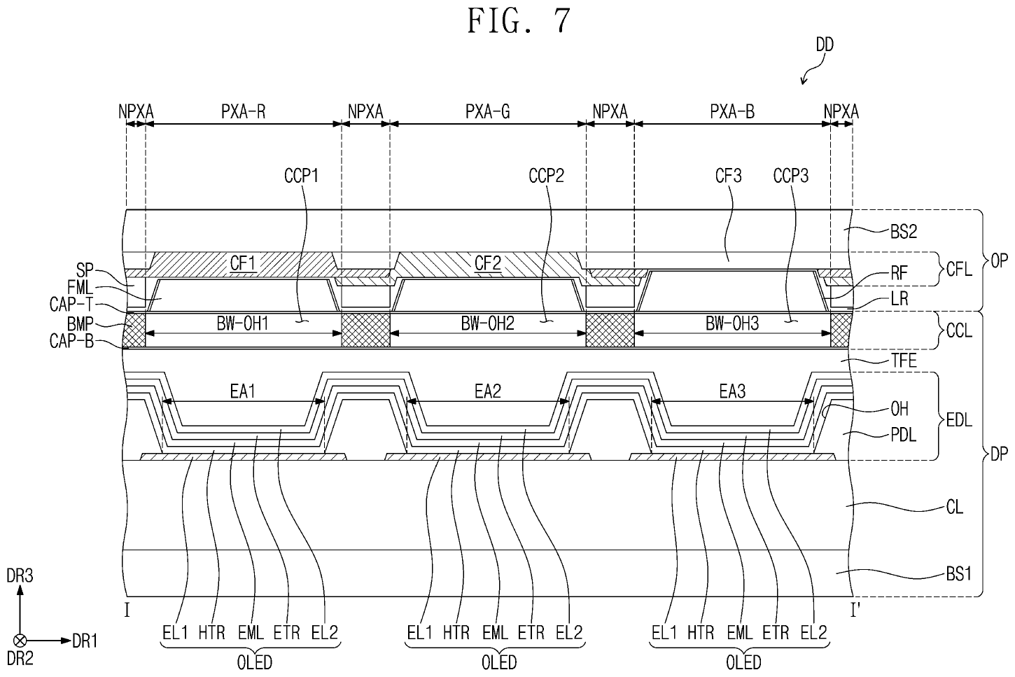

Referring to FIG. 7, the color filter panel OP may further include a reflection layer RF covering the sides of the spacer SP. Here, as shown in FIG. 7, the low refractive layer LR and the spacer SP may be disposed below the color filter layer CFL, and the reflection layer RF may be disposed at the sides of the spacer SP with the low refractive layer LR interposed therebetween. By way of example, as shown in FIG. 7, the low refractive layer LR may be omitted. The reflection layer RF may include a metal. The reflection layer RF may include a metal of a high reflectivity. For example, the reflection layer RF may include aluminum (Al) or silver (Ag). The reflection layer RF may reflect the incident light on the surface of the reflection layer RF.

As the color filter panel OP has the above-described structure, the side loss may be reduced before the light provided from the display panel DP passes the color filter layer CFL. By way of example, unlike the disclosure, for a color filter panel of the structure without the spacer SP, the side loss may be generated by, of light passing through the light control layer CCL, a light component that heads towards a portion in which the color filters CF1, CF2, CF3 are disposed to overlap each other, but does not head towards a portion with only the first color filter CF1 disposed therein, a portion with only the second color filter CF2 disposed therein, or a portion with only the third color filter CF1 disposed therein. On the contrary, for the color filter panel OP of the above-described structure according to the disclosure, a light component, which heads towards a portion with the color filters CF1, CF2, CF3 overlapping each other, may be reflected by the reflection layer RF disposed at the sides of the spacer SP to change the path thereof. The path-changed light component may head towards a portion with only the first color filter CF1 disposed therein, a portion with only the second color filter CF2 disposed therein, and a portion with only the third color filter CF3 disposed therein. Accordingly, the light extraction efficiency of the display device DD may be improved.

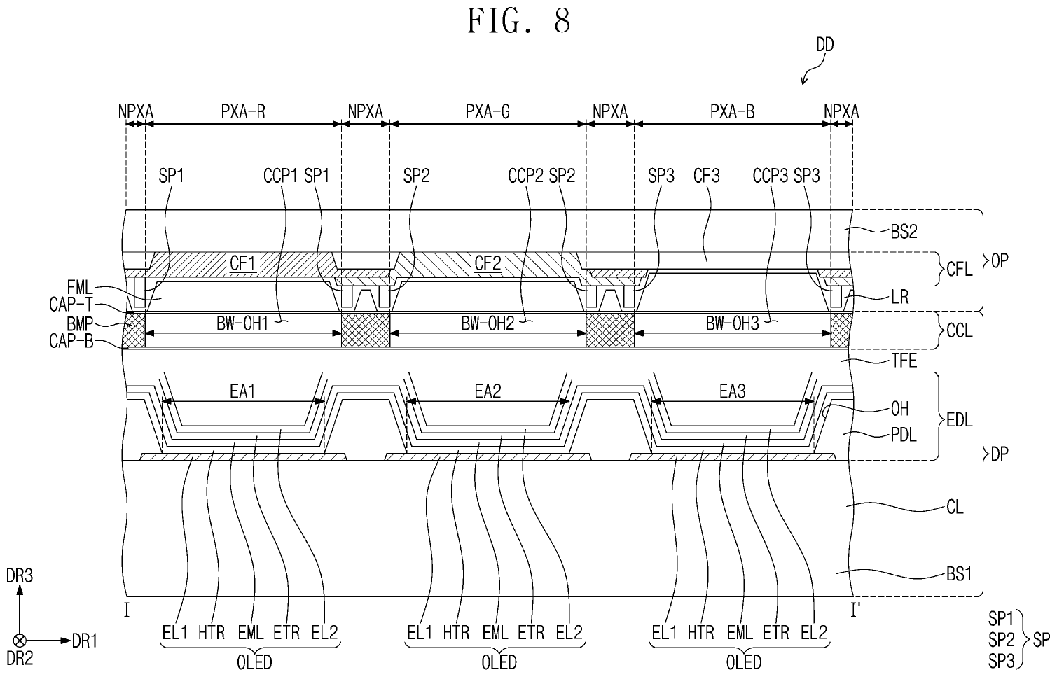

Referring to FIG. 8, the spacer SP may be disposed between the color filer layer CFL and the low refractive layer LR. The spacer SP may be disposed directly below the color filter layer CFL, and thus the top surface of the spacer SP may contact the color filter layer CFL. The sides of the spacer SP may be covered by the low refractive layer LR. For example, the low refractive layer LR may be disposed at the sides of the spacer SP protruding on the bottom surface of the color filter layer CFL in the third direction DR3.

Unlike what is shown in FIGS. 5 to 7, the spacer SP may be constituted with spacers SP1, SP2, SP3. For example, the spacer SP may include the first spacer SP1, the second spacer SP2, and the third spacer SP3. In a plan view, the first spacer SP1, the second spacer SP2, and the third spacer SP3 may be spaced apart from each other. In a plan view, the first spacer SP1 may surround the first pixel area PXA-R, the second spacer SP2 may surround the second pixel area PXA-G, and the third spacer SP3 may surround the third pixel area PXA-B.

As the color filter panel OP has the above-described structure, the side loss may be reduced before the light provided from the display panel DP passes the color filter layer CFL. By way of example, unlike the disclosure, for a color filter panel of the structure without the spacer SP, the side loss may be generated by, of light passing through the light control layer CCL, a light component that heads towards a portion in which the color filters CF1, CF2, CF3 are disposed to overlap each other, but does not head towards a portion with only the first color filter CF1 disposed therein, a portion with only the second color filter CF2 disposed therein, or a portion with only the third color filter CF1 disposed therein. On the contrary, for the color filter panel OP of the above-described structure according to the disclosure, a light component, which heads towards a portion with the color filters CF1, CF2, CF3 overlapping each other, is refracted or reflected by the low refractive layer LR to change the path thereof. The path-changed light component may head towards a portion with only the first color filter CF1 disposed therein, a portion with only the second color filter CF2 disposed therein, and a portion with only the third color filter CF3 disposed therein. Accordingly, the light extraction efficiency of the display device DD may be improved.

The display device DD may further include a filling layer FML disposed between the display panel DP and the color filter panel OP. The color filter panel OP may include an opening defined by the foregoing spacer SP. The top surface and the side of the opening in the color filter panel OP may be covered by the low refractive layer LR. The filling layer FML may be disposed in the opening in the color filer panel OP. The filling layer FML may charge between the display panel DP and the color filter panel OP. The filling layer FML may function as a buffer between the display panel DP and the color filter panel OP. The filling layer FML may have a shock absorption function and increase the strength of the display device DD. The filling layer FML may be provided from a charging resin including a polymer resin. For example, the filling layer FML may include a charging resin including an acrylic-based resin, an epoxy-based resin or the like within the spirit and the scope of the disclosure.

In case that the spacer SP is constituted with spaced spacers SP1, SP2, SP3 as in FIG. 8, the filling layer FML may also be disposed between the spacers SP1, SP2, SP3. By way of example, the filling layer FML may also be disposed between the first and second spacers SP1, SP2, between the second and third spacers SP2, SP3, and the first and third spacers SP1, SP3.

According to the description above, the display device according to the disclosure may include the spacer surrounding the pixel area and also may include the low refraction layer or reflection layer disposed at the sides of the spacer, thereby reducing the side loss of the light provided from the display panel to improve the light extraction efficiency.

While this disclosure has been described with reference to embodiments thereof, it will be clear to those of ordinary skill in the art to which the disclosure pertains that various changes and modifications may be made to the described embodiments without departing from the spirit and scope of the disclosure and as defined in the appended claims and their equivalents. Thus, the scope of the disclosure shall not be restricted or limited by the foregoing description, but may be determined by the broadest permissible interpretation of the following claims.

What is claimed is:

1. A display device comprising:
a display panel comprising a light emitting element layer and a light control layer disposed on the light emitting element layer; and
a color filter panel disposed on the display panel, wherein
the color filter panel comprises:
a base layer;
a color filter layer disposed below the base layer;
a low refractive layer disposed below the color filter layer; and
a spacer disposed between the color filter layer and the low refractive layer, and
sides of the spacer are covered by the low refractive layer.

2. The display device of claim 1, further comprising:
a pixel area and a peripheral area surrounding the pixel area,
wherein the spacer surrounds the pixel area in a plan view.

3. The display device of claim 1, further comprising:
a filling layer disposed between the display panel and the color filter panel, wherein
the color filter panel comprises an opening defined by the spacer, and
the filling layer is disposed in the opening of the color filter panel.

4. The display device of claim 1, wherein the low refractive layer comprises an inorganic layer.

5. The display device of claim 4, wherein the inorganic layer comprises at least one of silicon oxide, silicon nitride, and silicon oxynitride.

6. The display device of claim 4, wherein a refractive index of the inorganic layer is in a range of about 1.3 to about 1.45.

7. The display device of claim 1, wherein the low refractive layer comprises an organic layer disposed below the color filter layer and an inorganic layer disposed below the organic layer.

8. The display device of claim 7, wherein
the organic layer comprises hollow particles or voids, and
the inorganic layer comprises at least one of silicon oxide, silicon nitride, and silicon oxynitride.

9. The display device of claim 7, wherein
a refractive index of the organic layer is in a range of about 1.15 to about 1.35, and
a refractive index of the inorganic layer is in a range of about 1.3 to about 1.45.

10. The display device of claim 1, wherein
the color filter panel further comprises a reflection layer disposed at sides of the spacer with the low refractive layer disposed between the spacer and the reflection layer, and
the reflection layer comprises a metal.

11. The display device of claim 1, further comprising:
a first pixel area, and a second pixel area spaced apart from the first pixel area, wherein
the spacer comprises a first spacer and a second spacer spaced apart from the first spacer, and
the first spacer surrounds the first pixel area, and the second spacer surrounds the second pixel area in a plan view.

12. A display device comprising:
a display panel comprising a light emitting element layer and a light control layer disposed on the light emitting element layer; and
a color filter panel disposed on the display panel,
wherein the color filter panel comprises:
a base layer;
a color filter layer disposed below the base layer;
a spacer disposed below the color filter layer; and
a reflection layer covering sides of the spacer.

13. The display device of claim 12, wherein the reflection layer comprises a metal.

14. The display device of claim 12, further comprising:
a pixel area and a peripheral area surrounding the pixel area,
wherein the spacer surrounds the pixel area in a plan view.

15. The display device of claim 12, further comprising:
a filling layer disposed between the display panel and the color filter panel, wherein
the color filter panel comprises an opening defined by the spacer, and
the filling layer is disposed in the opening of the color filter panel.

16. The display device of claim 12, wherein the color filter panel further comprises a low refractive layer disposed below the color filter layer and between the spacer and the reflection layer.

17. The display device of claim 16, wherein the low refractive layer comprises an inorganic layer.

18. The display device of claim 17, wherein
the inorganic layer comprises at least one of silicon oxide, silicon nitride, and silicon oxinitride, and
a refractive index of the inorganic layer is in a range of about 1.3 to about 1.45.

19. The display device of claim 16, wherein the low refractive layer comprises an organic layer disposed below the color filter layer, and an inorganic layer disposed below the organic layer.

20. The display device of claim 19, wherein
the organic layer comprises hollow particles or voids, and a refractive index of the organic layer is in a range of about 1.15 to about 1.35, and
the inorganic layer comprises at least one of silicon oxide, silicon nitride, and silicon oxynitride, and a refractive index of the inorganic layer is in a range of about 1.3 to about 1.45.

21. The display device of claim 12, comprising:
a first pixel area; and
a second pixel area spaced apart from the first pixel area, wherein
the spacer comprises a first spacer and a second spacer spaced apart from the first spacer, and
the first spacer surrounds the first pixel area, and the second spacer surrounds the second pixel area in a plan view.

22. A display device comprising:
a pixel area and a peripheral area surrounding the pixel area;
a display panel comprising a light emitting element layer and a light control layer disposed on the light emitting element layer; and
a color filter panel disposed on the display panel, wherein
the color filter panel comprises:
a base layer;
a color filter layer disposed below the base layer;
a spacer disposed below the color filter layer; and
a low refractive layer disposed below the color filter layer; and
the spacer surrounds the pixel area in a plan view.

23. The display device of claim 22, wherein
the spacer is disposed between the color filter layer and the low refractive layer, and
the low refractive layer covers sides of the spacer.

24. The display device of claim 22, further comprising:
a filling layer disposed between the display panel and the color filter panel, wherein
the color filter panel comprises an opening defined by the spacer, and
the filling layer is disposed in the opening of the color filter panel.

25. The display device of claim 22, wherein
the color filter panel further comprises a reflection layer disposed at sides of the spacer with the low refractive layer disposed between the spacer and the reflection layer, and
the reflection layer comprises a metal.

26. The display device of claim 22, wherein
the pixel area comprises a first pixel area and a second pixel area spaced apart from the first pixel area,
the spacer comprises a first spacer and a second spacer spaced apart from the first spacer, and
the first spacer surrounds the first pixel area, and the second spacer surrounds the second pixel area in a plan view.
